(19) United States
(12) Patent Application Publication
(10) Pub. No.: US 2008/0237807 A1
(43) Pub. Date: Oct. 2, 2008

(54) SEMICONDUCTOR DEVICE

(75) Inventors: Seiji MIYOSHI, Ora-gun (JP); Tetsuya Okada, Kumagaya-shi (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD, Moriguchi-shi (JP); SANYO SEMICONDUCTOR CO., LTD., Ora-gun (JP)

(21) Appl. No.: 12/055,498

(22) Filed: Mar. 26, 2008

(30) Foreign Application Priority Data
Mar. 28, 2007 (JP) 2007-085260

(51) Int. Cl. H01L 29/40

(52) U.S. Cl. 257/621; 257/E29.112

(57) ABSTRACT

A second electrode is selectively brought into contact with a semiconductor substrate. Specifically, an insulating film having opening portions is provided on the second principal surface of the semiconductor substrate, and the second electrode is provided on the insulating film. The second electrode comes into contact with the second principal surface of the semiconductor substrate through the opening portions. The total area of the opening portions is approximately the half of the total area of the second principal surface of the semiconductor substrate. Consequently, minority carriers (holes) are prevented by the insulating film from being drawn out, and thus, the loss of the minority carriers around the second electrode is decreased. Accordingly, the conductivity modulation effect is improved. Therefore, the forward voltage can be decreased even with a structure in which the impurity concentration of a p type impurity region is decreased in order to shorten a reverse recover time.

This application claims priority from Japanese Patent Application Number JP 2007-85260 filed on Mar. 28, 2007, the content of which is incorporated herein by reference in its entirety.

### BACKGROUND OF THE INVENTION

1. Field of the Invention

The present invention relates to a semiconductor device, and more particularly relates to a semiconductor device with a decreased forward voltage.

2. Description of the Related Art

FIG. 7 is a cross-sectional view showing a pn-junction diode 60 as an example of a conventional semiconductor device.

In the pn-junction diode 60, an n− type semiconductor layer 52 is stacked on an n+ type silicon semiconductor substrate 51. Moreover, a p type impurity region 53 is provided by, for example, diffusing a high-concentration p type impurity, in the surface of the n− type semiconductor layer 52. An anode electrode 55 is provided on the surface of the p type impurity region 53, while a cathode electrode 58 is provided on the entire back surface of the n+ type silicon semiconductor substrate 51. This technology is described for instance in Japanese Patent Application Publication No. Hei.10-335679 (Page 20, FIG. 39).

In a pn-junction diode (Fast Recovery Diode: FRD) capable of a high-speed switching, it is required to shorten a reverse recovery time trr that is a time taken for releasing a charge (termed as a reverse recovery charge) Qrr stored therein.

As a way to shorten the reverse recovery time trr, the following is conceivable. The amount of injection of holes into the n− type semiconductor layer 52 which serves as a drift layer is decreased by reducing the impurity concentration of the p type impurity region 53.

However, the reduction in the impurity concentration of the p type impurity region 53 naturally leads to a decrease in the amount of carriers (holes) stored in the n− type semiconductor layer 52, and thus resulting in a reduction in the conductivity modulation effect. Accordingly, there arises a problem that a forward voltage VF at and near the rated current is increased.

### SUMMARY OF THE INVENTION

The invention provides a semiconductor device that includes a semiconductor substrate comprising a first principal surface and a second principal surface, an element region formed in the first principal surface and configured to modulate a conductivity thereof, a first electrode formed on and connected to the element region, an insulating film disposed on the second principal surface and having a plurality of opening portions formed therein, and a second electrode disposed on the insulating film so as to be in contact with the second principal surface through the opening portions.

### BRIEF DESCRIPTION OF THE DRAWINGS

FIGS. 1A, 1B and 1C are plan views for explaining a semiconductor device of a preferred embodiment of the present invention.

FIG. 2 is a cross-sectional view for explaining the semiconductor device of the embodiment of the present invention.

FIG. 3 is an enlarged cross-sectional view for explaining the semiconductor device of the embodiment of the present invention.

FIG. 4 is a characteristic diagram for explaining the semiconductor device of the embodiment of the present invention.

FIG. 5 is a characteristic diagram for explaining the semiconductor device of the embodiment of the present invention.

FIG. 6 is a characteristic diagram for explaining the semiconductor device of the embodiment of the present invention.

FIG. 7 is a cross-sectional view for explaining a conventional semiconductor device.

### DESCRIPTION OF THE EMBODIMENT

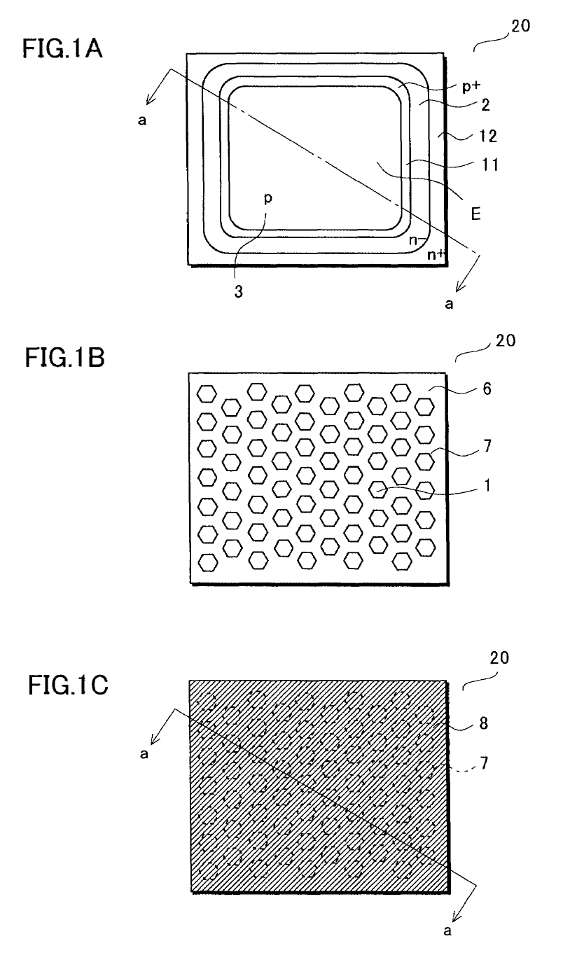

With reference to FIGS. 1A, 1B, and 1C, as well as 2 to 6, an embodiment of the present invention will be described in detail by taking a pn-junction diode as an example.

A semiconductor device 20 of this embodiment includes a semiconductor substrate SB, an element region E, a first electrode 5, an insulating film 6, opening portions 7, and a second electrode 8.

FIGS. 1A to 1C show the semiconductor device 20 of this embodiment. FIG. 1A is a plan view showing a first principal surface side of the semiconductor device 20; FIG. 1B is a plan view showing the insulating film 6 on a second principal surface side of the semiconductor device 20; and FIG. 1C is a plan view showing a state where the second electrode 8 is provided on the second principal surface side. Note that, the first electrode 5 and an insulating film on the first principal surface side are not shown in FIG. 1A.

The semiconductor substrate SB includes, for example, an n+ type silicon semiconductor substrate and an n− type semiconductor layer, and has the first and second principal surfaces. The n− type semiconductor layer is formed by epitaxial growth or the like on the n+ type silicon semiconductor substrate.

See FIG. 1A. On the first principal surface side of the semiconductor substrate SB (the n− type semiconductor layer 2), a p type impurity region 3 is provided in order to create the conductivity-modulation-type element region E which makes the n type semiconductor substrate SB a drift layer. In addition, a guard ring 11 and an annular 12 are provided in a manner of surrounding the outer side of the p type impurity region 3. The guard ring 11 and the annular 12 are highly concentrated p type and n type impurity regions, respectively.

Here, a pn-junction diode is formed in the element region E as an example. The element region E is a region in which the semiconductor device 20 actually performs its operation. In this embodiment, the element region E indicates a region inside the guard ring 11, for example. The first electrode 5, which will be described later, is provided on the first principal surface side of the semiconductor substrate SB.

As shown in FIG. 1B, the insulating film 6 is provided entirely on the second principal surface side of the semiconductor substrate SB. The insulating film 6 is, for example, an oxide film, and multiple opening portions 7 are selectively arranged in the insulating film 6.

The opening portions 7 have a uniform shape (a uniform size), and are arranged so that the center portions of each adjacent two of the opening portions 7 are spaced apart from each other at an equal distance. The shape of each opening portion 7 is an equilateral hexagon. The total area of the opening portions 7 is 35% to 80% of the area of the second principal surface of the semiconductor substrate SB.

As an example, when the area (chip size) of the second principal surface of the semiconductor substrate SB are, for example, approximately 3 mm×3 mm, the area of each opening portion 7 is approximately 1000 μm². Each adjacent two of the opening portions 7 are arranged spaced apart by approximately 15 μm from each other.

See FIG. 1C. The second electrode 8 is provided on the second principal surface side to cover the insulating film 6, and is in contact with the second principal surface (the n+ type silicon semiconductor substrate) of the semiconductor substrate SB through the opening portions 7 indicated by the dotted lines. The second electrode 8 is a back electrode of the semiconductor device 20, and serves as a cathode electrode in this embodiment.

The second electrode 8 has a multilayer metal structure including Ti, Ni, and Ag, layers stacked in this order from the second principal surface side. It is not preferable to use eutectic bonding for bonding the semiconductor device 20 (semiconductor chip) to a supporting member such as a lead frame when the chip size is not less than 0.6 mm×0.6 mm. This is because unevenness, and cracking due to the vibration, are likely to occur. For this reason, when the chip size is large, an adhesive is preferably used for the bonding.

In addition, when the chip size is smaller than 0.6 mm×0.6 mm, for example, eutectic bonding can be used for bonding the semiconductor device 20 to the supporting member such as a lead frame. In this case, the second electrode 8 employs a multilayer metal structure including NiCr and Au layers stacked in this order from the second principal surface side, and is bonded to the supporting member (made of, for example, Cu) by eutectic bonding.

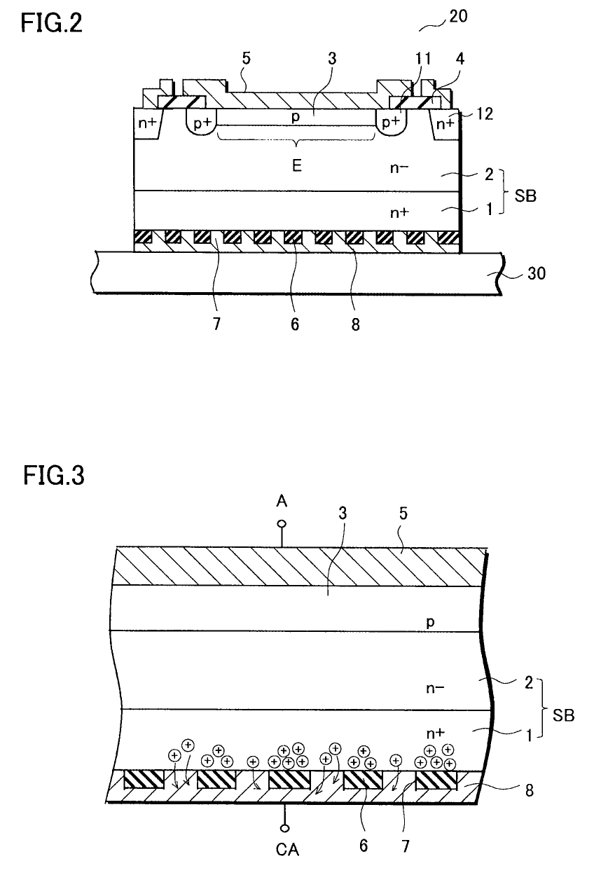

FIG. 2 is a cross-sectional view taken along the line a-a in FIG. 1, and shows a state where the semiconductor device 20 is bonded to a supporting member 30.

The semiconductor substrate SB includes the n+ type silicon semiconductor substrate 1 and the n− type semiconductor layer 2, which is formed by, for example, epitaxial growth on the n+ type silicon semiconductor substrate 1.

On the first principal surface side of the semiconductor substrate SB (the surface of the n− type semiconductor layer 2), the p type impurity region 3 is provided. Moreover, an insulating film 4, such as an oxide film, and the first electrode 5 are provided on the first principal surface side. The insulating film 4 has an opening portion corresponding to the p type impurity region 3 in order for the first electrode 5 to come into contact with the p type impurity region 3. The first electrode 5 is a surface electrode formed of an aluminum (Al) layer or the like, and serves as an anode electrode in this embodiment.

On the second principal surface, the second electrode 8 is provided to cover the insulating film 6 having the opening portions 7 provided therein. This makes the total contact area of the second electrode 8 with the semiconductor substrate SB 35% to 80% of the area of the semiconductor substrate SB. However, the bonding area of the second electrode 8 and the supporting member 30, such as a lead frame, holds as much as the area (chip size) of the semiconductor substrate SB. Consequently, the same bonding strength as that of the conventional case can be secured.

In this embodiment, the contact area of the second electrode 8 with the semiconductor substrate SB is reduced, so that the loss of minority carriers (holes) around the second electrode 8 is decreased. As a result, the conductivity modulation effect can be improved.

FIG. 3 is an enlarged cross-sectional view showing around the second electrode 8 at the time when a forward voltage VF is applied to the semiconductor device 20.

When a positive electric potential and a negative electric potential are applied respectively to the first electrode (anode electrode) 5 and the second electrode (cathode electrode) 8, injection of holes from the p type impurity region 3 into the n− type semiconductor layer 2 occurs. Consequently, the conductivity of the n− type semiconductor layer 2 (drift layer) is modulated and the semiconductor device 20 becomes conductive, and thus, the current flows from the first electrode 5 into the second electrode 8.

In this event, around the second electrode 8, the minority carriers (holes) in and near the opening portions 7 in the insulating film 6 are drawn to the second electrode 8. However, the minority carriers (holes) around the insulated film 6 in which the opening portions 7 are not provided are blocked by the insulating film 6 to be stored. As a result, the conductivity modulation effect is improved, and thus, the forward voltage VF is decreased.

In other words, even if the pn-junction diode in which the impurity concentration of the p type impurity region 3 is decreased in order to shorten the reverse recovery time trr is used, the conductivity modulation effect can still be improved around the second electrode 8.

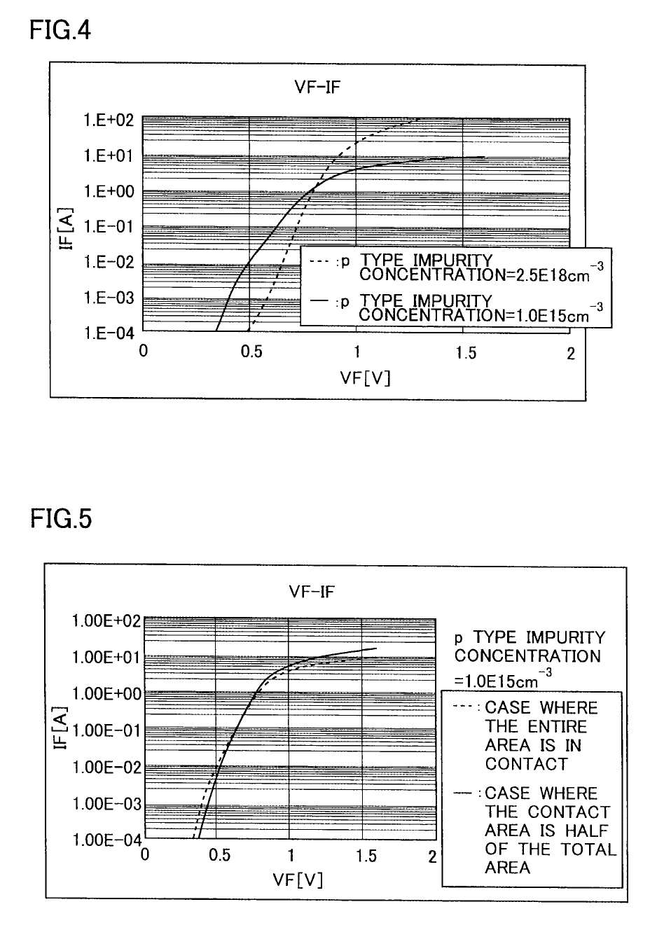

FIGS. 4 and 5 show the forward voltage VF—forward current IF characteristics in relation to the impurity concentration of the p type impurity region 3.

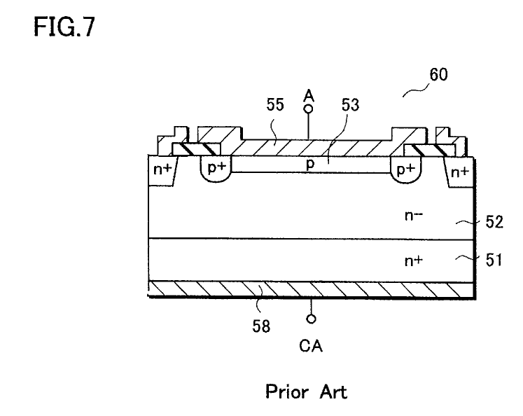

FIG. 4 shows the forward voltage VF—forward current IF characteristics of two types of impurity concentrations of the conventional structure (shown in FIG. 7). The dotted line and the solid line show the impurity concentrations of the p type impurity region 3 at 2.5E18 cm⁻³ and 1.0E15 cm⁻³, respectively.

As can be seen here, when the forward current IF is 5 A, the forward voltage VF increases by approximately 0.3 V by reducing the impurity concentration of the p type impurity region 3.

FIG. 5 shows a comparison between the conventional structure and the structure of this embodiment, in terms of the forward voltage VF—forward current IF characteristics. The dotted line shows a case where the second electrode is in contact with the entire surface of the semiconductor substrate SB as in the conventional structure. The solid line shows a case where the contact area of the second electrode 8 with the semiconductor substrate SB is half of the total area of the semiconductor substrate SB as in the structure of this embodiment. In addition, the impurity concentration of the p type impurity region is 1.0E15 cm⁻³, which is shown in FIG. 4.

As shown in FIG. 5, according to this embodiment, the decrease (for example, decreasing to the half of the total chip size) in the contact area of the second electrode 8 with the semiconductor substrate SB results in, when the forward current IF is not less than approximately 0.1 A, the decrease in the forward voltage VF as compared with the conventional forward voltage VF in the same forward current IF.

In FIG. 4, in a case where the impurity concentration of the p type impurity region is decreased, the forward voltage VF is low (low VF) when the forward current IF is not more than approximately 1 A. However, in the region where the forward current IF exceeds 1 A, the forward voltage VF in the same forward current IF increases (FIG. 4).

However, in this embodiment, the decrease in the contact area results in the decrease in the forward voltage VF in the same forward current IF because the forward voltage VF is reversed in the region where the forward current IF is not less than approximately 0.1 A. Note that, when the forward current IF is not more than approximately 0.1 A, it is preferable that the entire area of the second electrode (cathode electrode) be in contact with the semiconductor substrate SB but only when compared to the case where the second electrode is in contact with half of the total area of the semiconductor substrate SB, with a given same impurity concentration.

The forward voltage VF is low when the forward current IF is not more than approximately 1 A (FIG. 4) with a low impurity concentration of the p type impurity region, as compared to the case with a high impurity concentration (FIG. 4). Even when the forward current IF is not more than 0.1 A (FIG. 5) at which the forward voltage VF increases, it is possible to obtain a lower forward voltage VF than that of the conventional structure (the pn-junction diode 60 in which the entire area of the second electrode is in contact with the semiconductor substrate SB, and of which the impurity concentration of the p type impurity region is high).

Note that, since the insulating film 6 narrows the current path, the current resistance slightly increases. However, the appropriate determinations of the area size and the arrangement of the opening portions 7 makes it possible to obtain an improved conductivity modulation effect enough to cover the increased amount of the current resistance.

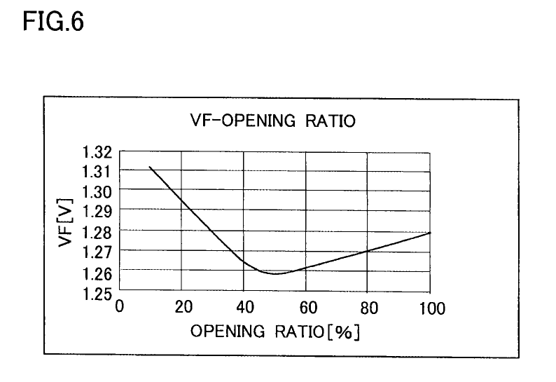

FIG. 6 shows the relationship between the opening ratio of the opening portions 7 and the forward voltage VF. The horizontal axis shows the opening ratio (%) indicating a ratio of the total area of the opening portions 7 to the area of the second electrode. The vertical axis shows the value of the forward voltage VF (V) for each opening ratio.

With the given structure, when the total area of the opening portions 7 is the half of the total area of the second principal surface of the semiconductor substrate SB, the forward voltage VF can be most decreased.

As described above, in this embodiment, the semiconductor device 20 in which the pn-junction diode (FRD) is formed in the element region E is taken as an example, but the present invention is not limited to this example. For example, the present invention may be employed in any semiconductor device, such as a bipolar transistor and an insulated gate bipolar transistor (IGBT), in which a conductivity-modulation-type element is formed in an element region E.

According to this embodiment, firstly, the conductivity-modulationtype element and the first electrode (surface electrode) are provided on the first principal surface side of the semiconductor substrate, and the second electrode (back electrode) is provided on the second principal surface thereof. In the semiconductor device, the opening portions are provided in the insulating film covering the second principal surface, so that the second electrode provided on the insulating film is brought into contact with the semiconductor substrate through the opening portions. In this manner, the contact area of the second electrode with the semiconductor substrate is decreased, so that the loss of the minority carriers (holes) around the second principal surface is decreased. Consequently, the amount of stored carriers (holes) is increased.

Accordingly, even with the structure in which the impurity concentration of the p type impurity region is decreased in order to shorten the reverse recovery time trr, the conductivity modulation effect can still be improved around the second principal surface. Accordingly, the increase in the forward voltage VF at and near the rated current can be prevented.

Secondly, the total contact area of the second electrode (the total area of the opening portions) is set at approximately 35% to 80% of the area of the second principal surface of the semiconductor substrate. Accordingly, the forward voltage VF attributable to the minority carriers stored around the second electrode is decreased. This effect of the decrease covers the amount of increase in the resistance caused by the narrowing of the current path. As a result, the forward voltage VF, which is increased in the conventional structure, at and near the rated current can be decreased.

Thirdly, a plurality of opening portions have a uniform equilateral hexagonal shape, and arranged spaced apart from each other at an equal distance. Accordingly, the carriers do not concentrate at one place, and thus can be drawn evenly. In addition, the current path can be made uniform.

What is claimed is:

1. A semiconductor device comprising:
a semiconductor substrate comprising a first principal surface and a second principal surface;
an element region formed in the first principal surface and configured to modulate a conductivity thereof;
a first electrode formed on and connected to the element region;
an insulating film disposed on the second principal surface and having a plurality of opening portions formed therein; and
a second electrode disposed on the insulating film so as to be in contact with the second principal surface through the opening portions.

2. The semiconductor device of claim 1, wherein the total area of the opening portions is 35% to 80% of an area of the second principal surface.

3. The semiconductor device of claim 1, wherein the opening portions have a uniform shape, and each of the opening portions is separated from corresponding nearest opening portions by the same distance.

4. The semiconductor device of claim 1, wherein each of the opening portions is a hexagon.
